(19) United States
(12) Patent Application Publication
(10) Pub. No.: US 2009/0250260 A1
(43) Pub. Date: Oct. 8, 2009

(54) High density circuit board and manufacturing method thereof

(75) Inventor: Myung Sam Kang, Daejeon (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/155,756

(22) Filed: Jun. 9, 2008

(30) Foreign Application Priority Data
Apr. 7, 2008 (KR) 10-2008-0032013

(51) Int. Cl. H05K 1/02; B32B 38/10; B05D 5/12; C23F 1/02

(52) U.S. Cl. 174/267; 427/98.5; 156/247; 427/540; 427/555; 216/20

(57) ABSTRACT

The present invention relates to a high density circuit board for increasing the density of a circuit by impregnating fine circuit patterns inside a top part of a substrate, and a method for manufacturing the same.

In accordance with the present invention, a high density circuit board includes a substrate with fine circuit patterns impregnated inside top and bottom parts; a via formed inside the substrate to electrically conduct the fine circuit patterns of the top and bottom parts of the substrate each other; pads formed on the fine circuit patterns of the top part of the substrate; and solder resists formed on the top and bottom parts of the substrate, which can convert the circuit patterns into fine pitches and increase the degree of close adhesion between the substrate and the circuit patterns, thereby improving reliability.

### CROSS-REFERENCE TO RELATED APPLICATIONS

This application claims the benefit of Korean Patent Application No. 10-2008-0032013 filed with the Korea Intellectual Property Office on Apr. 7, 2008, the disclosure of which is incorporated herein by reference.

### BACKGROUND OF THE INVENTION

1. Field of the Invention

The present invention relates to a high density circuit board and a method for manufacturing the same; and, more particularly, to a high density circuit board with fine circuit patterns formed on a top part of a substrate and impregnated inside the top part of the substrate and pads used as bumps, and a method for manufacturing the same.

2. Description of the Related Art

Recently, with high density and high integration of a semiconductor integrated circuit used in electronic equipment, multi-pins of electrode terminals of the semiconductor integrated circuit and fine pitches of a circuit board to mount the semiconductor integrated circuit have been rapidly progressed.

As technology for mounting the semiconductor integrated circuit on the circuit board, flip chip mounting has been widely used to minimize wiring delay. At this time, in the flip chip mounting, after forming solder bumps on pads of the circuit board, electrode terminals of flip chips are typically joined by positioning them on the solder bumps.

However, to mount a next generation semiconductor integrated circuit having the gradually increased number of the electrode terminals on the circuit board, there is a need for forming the bumps corresponding to fine pitches of less than 100 μm on the circuit board, however, currently used solder bump forming technology is unsatisfactory for the need.

Further, the circuit board mounting the semiconductor integrated circuit has to be formed in circuit patterns with the fine pitches since the degree of integration thereof has been increased.

### SUMMARY OF THE INVENTION

The present invention relates to a circuit board with high density circuit patterns and it is an object of the present invention to provide a high density circuit board capable of converting the circuit patterns into fine pitches by impregnating the fine circuit patterns formed on a top part of a substrate inside the top part of the substrate and using pads as bumps and improving reliability by increasing the degree of close adhesion between the substrate and the circuit patterns.

In accordance with the first embodiment of the present invention, there is provided a high density circuit board including a substrate with fine circuit patterns impregnated inside top and bottom parts; a via formed inside the substrate to electrically conduct the fine circuit patterns of the top and bottom parts of the substrate each other; pads formed on the fine circuit patterns of the top part of the substrate; and solder resists formed on the top and bottom parts of the substrate, which can convert the circuit patterns into fine pitches and increase the degree of close adhesion between the substrate and the circuit patterns, thereby improving reliability.

At this time, the fine circuit patterns may have the width of less than 15 μm, and the fine circuit patterns, the pads, and the via may be made of Cu or Ag.

Further, the pads may have the width of less than 70 μm and top parts of the pads may be exposed outside the substrate.

Particularly, the solder resists may be formed in a height equal to or lower than that of the pads. Further, the solder resists on the bottom part of the substrate may be formed to open bottom parts of the fine circuit patterns on the bottom part of the substrate.

And, in accordance with the first embodiment of the present invention, there is provided a method for manufacturing the high density circuit board including the steps of: impregnating the fine circuit patterns inside the top and bottom parts of the substrate; forming a via hole to expose the fine circuit patterns on the bottom part of the substrate and forming dry film patterns on the top part of the substrate to open the via hole and regions where the pads are formed; burying the via hole and forming the pads by performing a plating process; and forming the solder resists on the top and bottom parts of the substrate to expose top parts of the pads after removing the dry film patterns.

At this time, the step of impregnating the fine circuit patterns inside the top and bottom parts of the substrate may include the steps of: joining first and second copper clad laminate units on top and bottom parts with respect to a junction layer; forming the fine circuit patterns on the first and second copper clad laminate units; and reversing the first and second copper clad laminate units respectively by separating them from the junction layer and impregnating the fine circuit patterns inside the top and bottom parts of the substrate by pressing them with respect to the substrate.

Further, the first and second copper clad laminate units may be formed by sequentially stacking a first copper film, a different metal layer and a second copper film, the fine circuit patterns may be formed in a width of less than 15 μm, and the fine circuit patterns and the pads may be formed by using Cu or Ag.

Further, the via hole may be formed by using a laser processing method or an etching process and the method of the present invention may further include a step of performing a desmear process after forming the via hole.

And, the method of the present invention may further include a step of forming a metal seed layer before forming the dry film patterns and the metal seed layer may be formed by using Cu or Ag. At this time, the method of the present invention may further include a step of removing the metal seed layer formed on a lower part of the dry film pattern after removing the dry film patterns.

At this time, the pads may be formed in a width of less than 70 μm.

Further, the method of the present invention further may include a step of performing an etching process to remove the solder resists formed on the pads after forming the solder resists, and the etching process may use any one selected from a plasma etching process, a wet etching process or a reactive ion etching process.

The solder resists may be formed in a height equal to or lower than that of the pads.

Meanwhile, in accordance with the second embodiment of the present invention, there is provided a high density circuit board including a substrate with multi-layered circuit patterns inside and fine circuit patterns impregnated inside top and bottom parts; vias connected to the circuit patterns of each of layers to electrically conduct the fine circuit patterns each other; pads formed on the fine circuit patterns of the top part of the substrate; and solder resists exposing top parts of the pads and formed on the top and bottom parts of the substrate.

In addition, in accordance with the second embodiment of the present invention, there is provided a method for manufacturing the high density circuit board including the steps of: impregnating the fine circuit patterns inside the top and bottom parts of the substrate with the multi-layered circuit patterns inside; forming via holes to expose the fine circuit patterns on the bottom part of the substrate and forming the dry film patterns on the top part of the substrate to open the via hole and regions where the pads are formed; burying the via hole and forming the pads by performing a plating process; and forming the solder resists on the top and bottom parts of the substrate to expose the top parts of the pads after removing the dry film patterns.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is a cross-sectional perspective view showing a high density circuit board in accordance with a first embodiment of the present invention;

FIG. 2 is a perspective view showing the high density circuit board in accordance with the first embodiment of the present invention;

FIG. 3 is a plane-view showing the high density circuit board in accordance with the first embodiment of the present invention;

FIG. 4 to FIG. 13 are cross-sectional views showing a process for manufacturing the high density circuit board in accordance with the first embodiment of the present invention;

FIG. 14 is a cross-sectional view showing a high density circuit board in accordance with a second embodiment of the present invention; and

FIG. 15 is a cross-sectional view showing a high density circuit board in accordance with a modified embodiment of the present invention.

### DETAILED DESCRIPTION OF THE PREFERRED EMBODIMENTS

Hereinafter, in accordance with the present invention, a subject regarding to a technical configuration of a high density circuit board, a method for manufacturing the same and an operation effect thereof will be appreciated clearly through the following detailed description with reference to the accompanying drawings illustrating preferable embodiments of the present invention.

### First Embodiment

Hereinafter, a configuration of a high density circuit board and a method for manufacturing the same in accordance with a first embodiment of the present invention will be described in more detail with reference to the accompanying drawings.

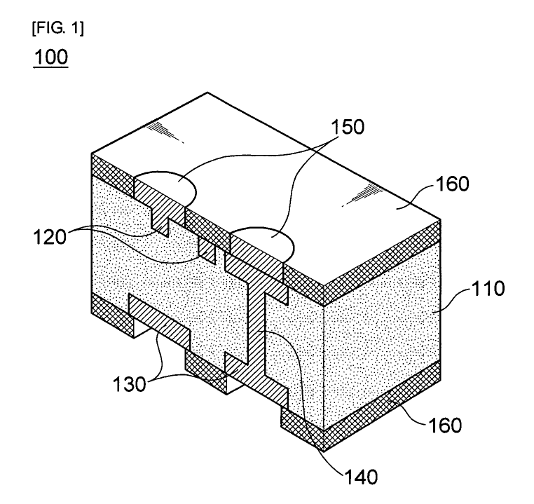

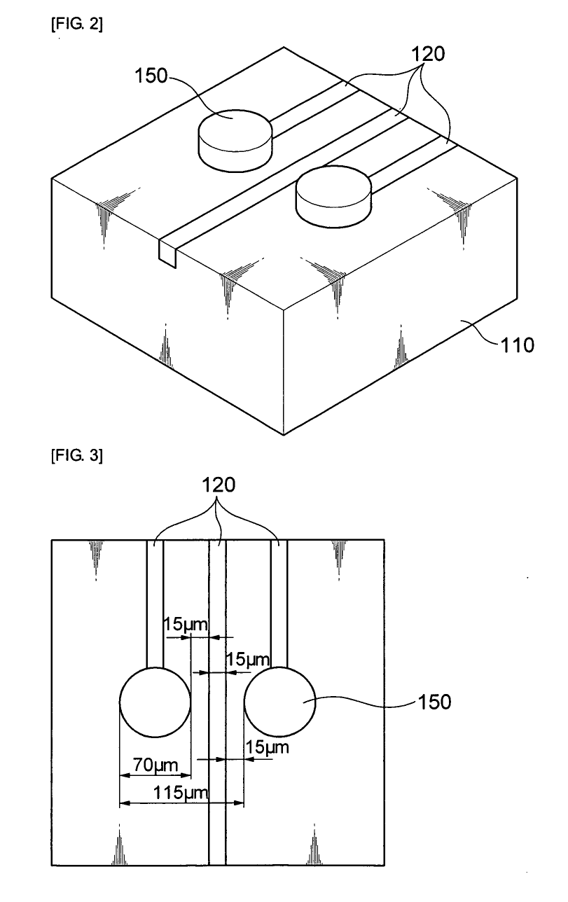

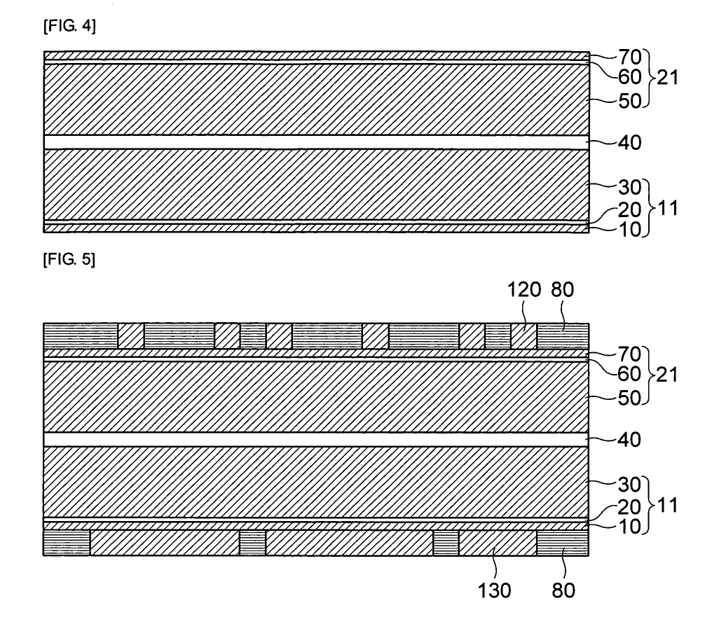

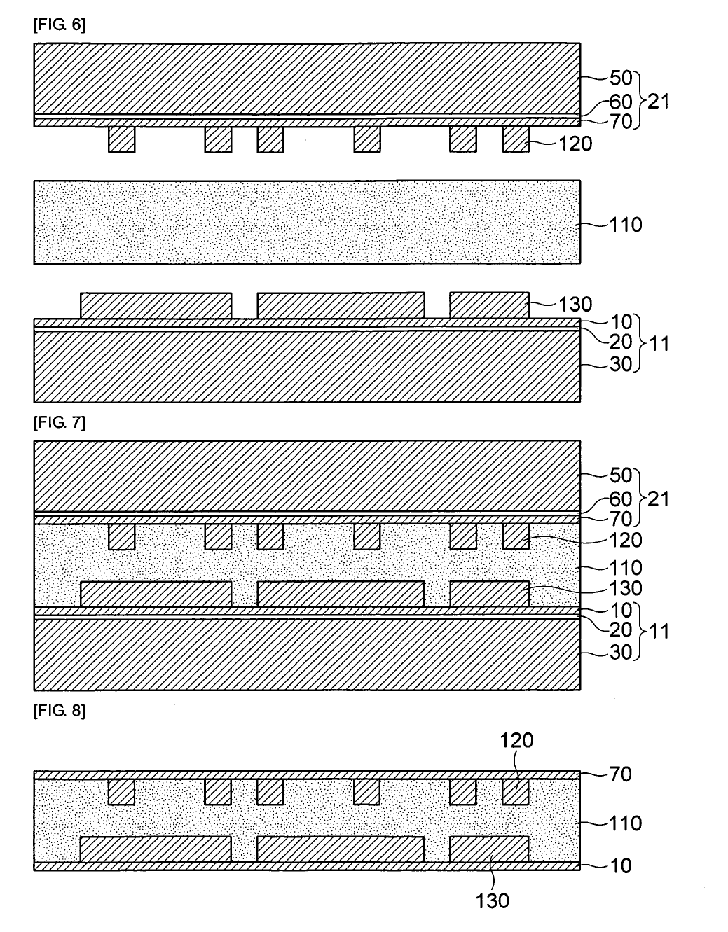

FIG. 1 is a cross-sectional perspective view showing a high density circuit board in accordance with the first embodiment of the present invention, FIG. 2 is a perspective view showing the high density circuit board in accordance with the first embodiment of the present invention and FIG. 3 is a plane-view showing the high density circuit board in accordance with the first embodiment of the present invention.

First of all, as shown in FIG. 1, in accordance with the first embodiment of the present invention, a high density circuit board 100 may include a substrate 110, top and bottom fine circuit patterns 120 and 130 impregnated inside top and bottom parts of the substrate 110, a via 140 to electrically conduct the top and bottom fine circuit patterns 120 and 130, pads 150 formed on the top fine circuit patterns 120 and solder resists 160 formed on the top and bottom parts of the substrate 110.

Particularly, as shown in FIG. 2, the top fine circuit patterns 120 are not adhered on a top surface of the substrate 110, but are formed by being impregnated inside the top part, thereby improving close adhesion force with the substrate 110.

Therefore, in order to satisfy high density, the top fine circuit patterns 120 are gradually narrowed but impregnated inside the top part of the substrate 110, which can increase an adhesive area to prevent the top fine circuit patterns 120 from being separated from the substrate 110 and reduce the thickness thereof.

Further, the pads 150 formed on the top parts of the top fine circuit patterns 120 may have a height equal to or higher than that of the solder resists 160. Accordingly, the pads 150 can be used as bumps since the pads 150 are exposed outside and have the predetermined height.

That is, when mounting high integrated components such as a flip chip on the top part of the high density circuit board 100, a process is simplified and a manufacturing cost is reduced by using the pads 150 as the bumps without an additional adhesive device such as a solder bump.

At this time, as shown in FIG. 3 representing a plane of the high density circuit board 100 in accordance with the first embodiment of the present invention, the top fine circuit patterns 120 may have fine patterns of less than 15 μm.

Further, the pads 150 may be formed in the size of less than 70 μm and preferably have a separation distance of more than 15 μm from the top fine circuit patterns 120 or the pads 150 adjacent to the pads 150.

At this time, the reason for securing the separation distance from the top fine circuit patterns 120 or the pads 150 adjacent to the pads 150 is not to be influenced by electric interference with the adjacent pads 150 or top fine circuit patterns 120 since the pads 150 and the top fine circuit patterns 120 are made of conductive material.

And, the top fine circuit patterns 120, the via 140 and the pads 150 may be made of conductive material such as Cu or Ag.

Meanwhile, the bottom fine circuit patterns 130 impregnated on a lower part of the substrate 110 are made of the same conductive material as the top fine circuit patterns 120. Further, the bottom fine circuit patterns are electrically connected to components mounted thereon since the solder resists 160 are not formed on bottom parts of the bottom fine circuit patterns 130 to open the bottom parts of the bottom fine circuit patterns 130.

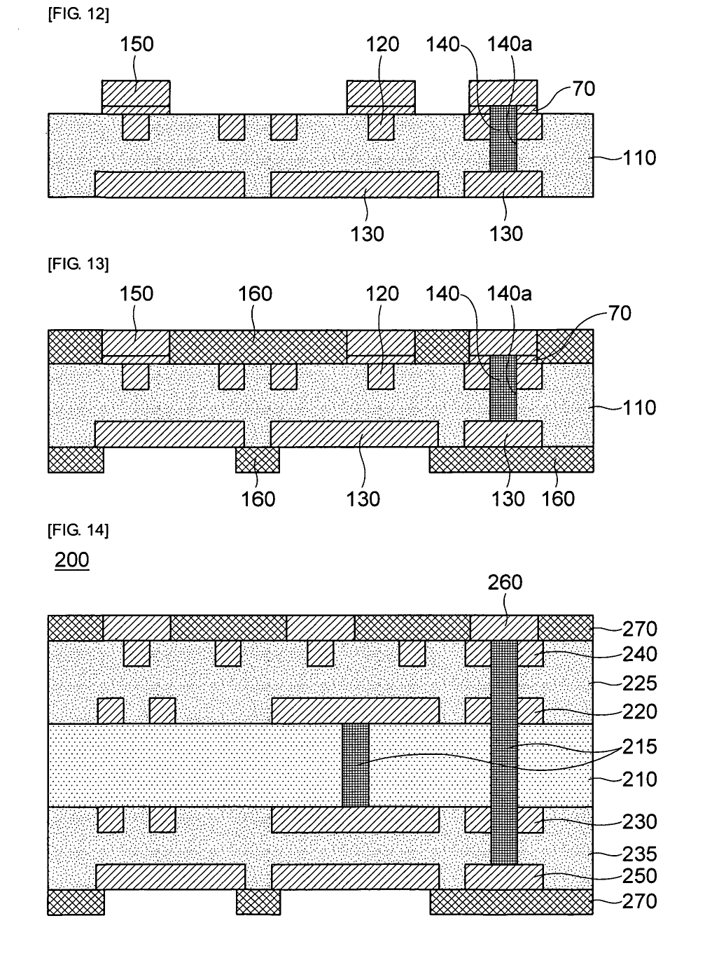

Hereinafter, a method for manufacturing the high density circuit board as formed above in accordance with the first embodiment of the present invention will be described in more detail with reference to the accompanying FIG. 4 to FIG. 13.

FIG. 4 to FIG. 13 are cross-sectional views showing a process for manufacturing the high density circuit board in accordance with the first embodiment of the present invention.

First of all, as shown in FIG. 4, in a method for manufacturing the high density circuit board 100 in accordance with the first embodiment of the present invention, a first copper clad laminate unit 11 and a second copper clad laminate unit 21 are formed respectively by sequentially stacking first copper films 10 and 70, different metal layers 20 and 60 and second copper films 30 and 50.

Then, the first and second copper clad laminate units 11 and 21 are adhered with respect to a junction layer 40 so that the second copper films 30 and 50 face each other.

After joining the first and second copper clad laminate units 11 and 12, as shown in FIG. 5, first film patterns 80 are formed to form the top and bottom fine circuit patterns 120 and 130 on the first copper films 10 and 70.

At this time, the first dry film patterns 80 are preferably patterned to have separation distances of at lease 15 μm so as to prevent the top fine circuit patterns 120 formed by a subsequent process from being influenced by electrical interference with the adjacent top fine circuit patterns 120.

After forming the first dry film patterns 80, the bottom fine circuit patterns 130 on the one first copper film 10 of the first copper clad laminate unit 11 and the top fine circuit patterns 120 on the other first copper film 70 of the second copper clad laminate unit 21 are formed respectively by performing the plating process.

Particularly, the plating process may use any one selected from an electroless or electro plating process by using the first copper films 10 and 70 as metal seed layers. Further, the top and bottom fine circuit patterns 120 and 130 may be formed by using Cu or Ag.

After forming the top and bottom fine circuit patterns 120 and 130, the first dry film patterns 80 remaining on the first copper films 10 and 70 are removed.

Then, as shown in FIG. 6, the first copper clad laminate unit 11 and the second copper clad laminate unit 21 are separated with respect to the junction layer 40 respectively. The thus-separated first and second copper clad laminate units 11 and 21 are reversed respectively and positioned so that the top and bottom fine circuit patterns 120 and 130 face each other, and then the substrate 110 is positioned between the first copper clad laminate unit 11 and the second copper clad laminate unit 21.

At this time, as shown in FIG. 7, the top and bottom fine circuit patterns 120 and 130 are impregnated inside the top and bottom parts of the substrate 110 by pressing the first copper clad laminate unit 11 and the second copper clad laminate unit 21 with respect to the substrate 110.

After impregnating the top and bottom fine circuit patterns 120 and 130 inside the top and bottom parts of the substrate 110, as shown in FIG. 8, the second copper films 30 and 50 and the different metal layers 20 and 60 of the first and second copper clad laminate units 11 and 21 are sequentially removed.

Particularly, when the thick second copper films 30 and 50 are removed, the different metal layers 20 and 60 are used as etch stopping films to prevent the first copper films 10 and 70 from being removed.

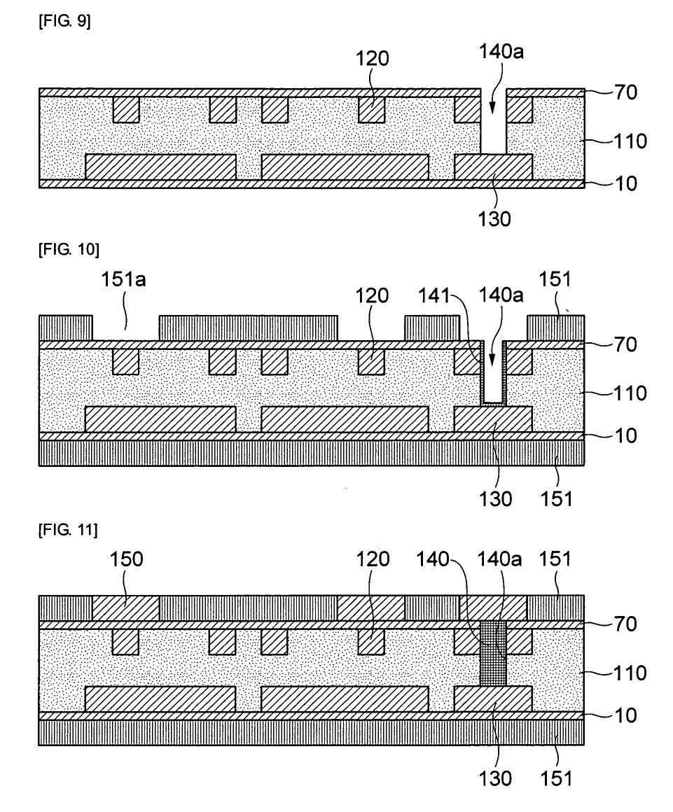

After removing the different metal layers 20 and 60 and the second copper films 30 and 50, as shown in FIG. 9, a via hole 140a is formed in the substrate 110 such that top part of the bottom fine circuit pattern 130 is exposed.

At this time, a method for processing the via hole 140a may use any one selected from an etching process to selectively etch even the top part of the bottom fine circuit pattern 130 by using a laser processing method or another etching process to etch after forming a dry film pattern to open only a via hole 140a forming region.

After forming the via hole 140a, a desmear process is preferably further performed to remove pieces of substrate 110 remaining on the via hole 140a by the etching process.

Then, as shown in FIG. 10, a metal seed layer 141 is deposited in the via hole 140a. At this time, the metal seed layer 141 may be formed by using any one selected from Cu or Ag of conductive material.

After forming the metal seed layer 141, second dry film patterns 151 are formed on the first copper films 10 and 70. Only pads forming regions on the first copper film are opened since the second dry film patterns 151 are patterns for forming the following pads.

As shown in FIG. 11, the pads 150 are formed on the open regions of the second dry film patterns 151 by performing the planting process by using the second dry film patterns 151 as plating stopping films and the via 140 is formed by growing the metal seed layer 141 and filling the via hole 140a.

At this time, the pads 150 and the via 140 have to be made of material with an electric characteristic, and therefore they are preferably formed by using any one of Cu or Ag of conductive material.

Further, the pads 150 are formed on the top parts of the fine circuit patterns 120 and preferably have the size of less than 70 μm. Particularly, the pads 150 are preferably formed to have a separation distance of at least 15 μm to prevent the pads from being influenced by electric interference with the adjacent pads 150 or top fine circuit patterns 120.

After forming the pads 150 and the via 140, the first copper films 10 and 70 on the top part of the substrate where the pads 150 are not formed are removed by performing an etching process.

Then, as shown in FIG. 13, the solder resists 160 are positioned on the top and bottom parts of the substrate 110 by pressing the solder resists with respect to the substrate 110.

And, it is preferable that bottom parts of the bottom fine circuit patterns 130 are opened so that the solder resists 160 formed on the bottom part of the substrate 110 are formed to expose the bottom fine circuit patterns 130 outside. At this time, because the bottom fine circuit patterns can be formed to have the wider widths than those of the top fine circuit patterns 120, they can be directly connected to external elements or connected to them through an additional formed solder bump or the like.

Particularly, the solder resists 160 formed on the top part of the substrate 110 are formed to be exposed outside by having the height equal to or lower than that of the pads 150.

Therefore, the pads 150 can be used as bumps without additional formation of the solder bump or the like on the pads 150 to form the high density circuit board 100.

Meanwhile, after forming the solder resists 160, in order to remove the solder resists 160 remaining on the pads 150 when pressing the solder resists 160, an etching process may be further performed.

At this time, it is preferable that the solder resists 160 is etched by using one of a plasma etching process, a wet etching process or a reactive ion etching process.

The performing of the etching process prevents junction force between the circuit board 100 and a semiconductor integrated circuit mounted thereon from being deteriorated due to the remaining solder resists 160, which can improve reliability.

As described above, the circuit board 100 manufactured by the method for manufacturing the high density circuit board in accordance with the first embodiment of the present invention, can prevent the top and bottom fine circuit patterns 120 and 130 from being separated from the substrate 110 by increasing close adhesion force between the top and bottom fine circuit patterns 120 and 130 and the substrate 110 through the impregnation of the top and bottom fine circuit patterns 120 and 130 inside the top and bottom parts of the substrate 110.

Further, the size of the pads can be reduced and the heights of the top and bottom fine circuit patterns 120 and 130 and the pads 150 can be reduced by impregnating the top and bottom fine circuit patterns 120 and 130 inside the substrate 110 and forming the pads thereon, thereby reducing the thickness of the circuit board 100.

### Second Embodiment

Hereinafter, a high density circuit board in accordance with the second embodiment of the present invention will be described in more detail with reference to the accompanying related drawings. Only, description for the same constructions as the first embodiment of the second embodiment will be omitted and only different constructions from those of the first embodiment will be described in detail.

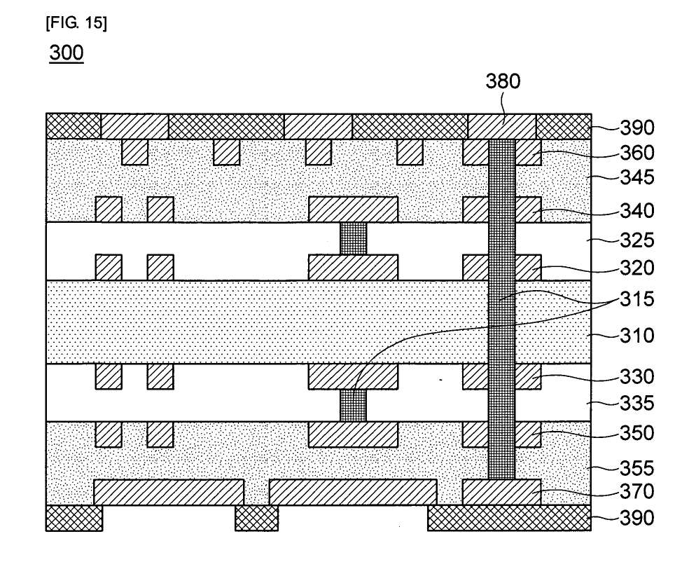

FIG. 14 is a cross-sectional view showing a high density circuit board in accordance with the second embodiment of the present invention and FIG. 15 is a cross-sectional view showing a modified embodiment of the high density circuit board in accordance with the second embodiment of the present invention.

First of all, as shown in FIG. 14, in the high density circuit board 200 in accordance with the second embodiment of the present invention, top and bottom fine circuit patterns 240 and 250 are impregnated inside top and bottom parts of first and third substrates 210, 225 and 235 with two-layered circuit patterns 220 and 230 inside.

At this time, inside the high density circuit board 200, a via 215 is formed to electrically conduct the top fine circuit patterns 240 and the bottom fine circuit patterns 250 each other.

Further, as shown in FIG. 15, in a high density circuit board 300 in accordance with a modified example of the second embodiment of the present invention, top and bottom fine circuit patterns 360 and 370 are impregnated inside top and bottom parts of first and fifth substrates 310, 325, 335, 345 and 355 with four-layered circuit patterns 320, 330, 340 and 350.

At this time, as shown in FIG. 14 and FIG. 15, the top and bottom fine circuit patterns 240, 250, 360 and 370 of the circuit boards 200 and 300 including plural circuit pattern layers are formed by the same method as the above-mentioned first embodiment.

That is, the top and bottom fine circuit patterns 240, 250, 360 and 370 formed on the first and second copper clad laminate units 11 and 21 may be impregnated in the substrate by reversing them to face each other and pressing them.

As described above, in accordance with the preferable embodiments of the present invention, the high density circuit board and the method for manufacturing the same have an advantage that it is possible to convert the circuit patterns into fine pitches by impregnating the fine circuit patterns formed on the top part of the substrate inside the top part of the substrate and using the pads formed on the top part of the substrate as the bumps.

Further, in accordance with the present invention, there is another advantage that it is possible to improve reliability by increasing the adhesion force between the substrate and the circuit patterns and preventing the circuit patterns from being separated from the substrate through the impregnating of circuit patterns inside the substrate.

As described above, although a few preferable embodiments of the present invention have been shown and described, it will be appreciated by those skilled in the art that substitutions, modifications and changes may be made in these embodiments without departing from the principles and spirit of the general inventive concept, the scope of which is defined in the appended claims and their equivalents.

1. A high density circuit board comprising:
a substrate including fine circuit patterns impregnated inside top and bottom parts;
a via formed inside the substrate to electrically conduct the fine circuit patterns of the top and bottom parts of the substrate each other;
pads formed on the fine circuit patterns of the top part of the substrate; and
solder resists formed on the top and bottom parts of the substrate.

2. The high density circuit board according to claim 1, wherein the fine circuit patterns include the width of less than 15 μm.

3. The high density circuit board according to claim 1, wherein the fine circuit patterns, the pads, and the via is made of Cu or Ag.

4. The high density circuit board according to claim 1, wherein the pads include the width of less than 70 μm.

5. The high density circuit board according to claim 1, wherein top parts of the pads are exposed outside the substrate.

6. The high density circuit board according to claim 1, wherein the solder resists are formed in a height equal to that of the pads.

7. The high density circuit board according to claim 1, wherein the solder resists are formed in a height lower than that of the pads.

8. The high density circuit board according to claim 1, wherein the solder resists on the bottom part of the substrate are formed to open bottom parts of the fine circuit patterns on the bottom part of the substrate.

9. A high density circuit board comprising:
a substrate including multi-layered circuit patterns inside and fine circuit patterns impregnated inside top and bottom parts;
vias connected to each layer of the circuit patterns to electrically conduct the fine circuit patterns each other;
pads formed on the fine circuit patterns of the top part of the substrate; and
solder resists exposing top parts of the pads and formed on the top and bottom parts of the substrate.

10. A method for manufacturing a high density circuit board comprising:
impregnating fine circuit patterns inside top and bottom parts of a substrate;
forming a via hole to expose the fine circuit patterns of the bottom part of the substrate and forming dry film patterns on the top part of the substrate to open the via hole and regions where the pads are formed;
burying the via hole and forming the pads by performing a plating process; and
forming solder resists on the top and bottom parts of the substrate to expose the top parts of the pads after removing the dry film patterns.

11. The method according to claim 10, wherein the step of impregnating the fine circuit patterns inside the top and bottom parts of the substrate comprising:
joining first and second copper clad laminate units on top and bottom parts with respect to a junction layer;
forming the fine circuit patterns on the first and second copper clad laminate units; and
impregnating the fine circuit patterns inside the top and bottom parts of the substrate by separating the first and second copper clad laminate units from the junction layer, reversing the first and second copper clad laminate units respectively, and pressing the first and second copper clad laminate units with respect to the substrate.

12. A method according to claim 10, wherein the first and second copper clad laminate units are formed by sequentially stacking a first copper film, a different metal layer and a second copper film.

13. A method according to claim 10, wherein the fine circuit patterns is formed in a width of less than 15 μm.

14. The method according to claim 10, wherein the fine circuit patterns and the pads are formed of Cu or Ag.

15. The method according to claim 10, wherein the via hole is formed by a laser processing method or an etching process.

16. The method according to claim 10, further comprising a performing a desmear process after forming the via hole.

17. The method according to claim 10, further comprising a forming a metal seed layer before forming the dry film pattern.

18. The method according to claim 17, wherein the metal seed layer is made of Cu or Ag.

19. The method according to claim 17, further comprising removing the metal seed layer formed on a bottom part of the dry film pattern after removing the dry film pattern.

20. The method according to claim 10, wherein the pads are formed in a width of less than 70 μm.

21. The method according to claim 10, further comprising performing an etching process for removing the solder resists formed on the pads after forming the solder resists.

22. The method according to claim 21, wherein the etching process uses any one selected from a plasma etching process, a wet etching process or a reactive ion etching process.

23. The method according to claim 10, wherein the solder resists are formed in a height equal to that of the pads.

24. The method according to claim 10, wherein the solder resists are formed in a height lower than to that of the pads.

25. A method for manufacturing a high density circuit board comprising:
impregnating fine circuit patterns inside top and bottom parts of a substrate with multi-layered circuit patterns inside;
forming a via hole to expose the fine circuit patterns on the bottom part of the substrate and forming dry film patterns on the top part of the substrate to open the via hole and regions where the pads are formed;
burying the via hole and forming the pads by performing a plating process; and
forming solder resists on the top and bottom parts of the substrate to expose the top parts of the pads after removing the dry film pattern.
